(19) United States
(12) Patent Application Publication
(10) Pub. No.: US 2001/0015811 A1
(43) Pub. Date: Aug. 23, 2001

(54) Test structure for metal CMP process control

(75) Inventors: Avi Ravid, Kfar Saba (IL); Vladimir Machavariani, Rishon Lezion (IL); Amit Weingarten, Ramat Gan (IL); David Scheiner, Ganei Yehuda (IL)

Correspondence Address: GREER, BURNS & CRAIN, 300 S WACKER DR, 25TH FLOOR, CHICAGO, IL, 60606, US

(73) Assignee: Nova Measuring Instruments Ltd.

(21) Appl. No.: 09/789,276

(22) Filed: Feb. 20, 2001

(30) Foreign Application Priority Data
Feb. 20, 2000 (IL) 134626
Jun. 6, 2000 (IL) 136608

(51) Int. Cl. G01B 11/30

(52) U.S. Cl. 356/600

(57) ABSTRACT

A test structure is presented to be formed on a patterned structure and to be used for controlling a CMP process applied to the patterned structure, which has a pattern area formed by spaced-apart metal-containing regions representative of real features of the patterned structure. The test structure thus undergoes the same CMP processing as the pattern area. The test structure comprises at least one pattern zone in the form of a metal area with at least one region included in the metal area and made of a material relatively transparent with respect to incident light, as compared to that of the metal.

### FIELD OF THE INVENTION

This invention is in the field of optical monitoring techniques, and relates to a test structure to be formed on a real metal-based patterned structure, and a method of controlling a process of chemical mechanical planarization (CMP) applied to the metal-based patterned structure utilizing the test structure. The invention is particularly useful in the manufacture of semiconductor devices such as wafers.

### BACKGROUND OF THE INVENTION

In the manufacture of semiconductor devices, aluminum has been used almost exclusively as the main material for interconnects. However, recent developments in this field of the art have shown that copper is posed to take over as the main on-chip conductor for all types of integrated circuits. Compared to aluminum, copper has a lower resistance, namely, less than 2 μω-cm, even when deposited in narrow trenches, versus more than 3 μω-cm for aluminum alloys. This property is critically important in high-performance microprocessors and fast static RAMs, since it enables signals to move faster by reducing the so-called “Resistance-Capacitance” (RC) time delay. Additionally, copper has a superior resistance to electro-migration, which leads to lower manufacturing costs, as compared to aluminum-based structures.

During the manufacture of semiconductor devices, a semiconductor wafer undergoes a sequence of photolithography-etching steps to produce a plurality of patterned layers (stacks). Then, depending on the specific layers' structure or a specific production process, the uppermost layer of the wafer may or may not undergo a CMP process to provide a smooth surface of this layer.

When manufacturing the aluminum-based structures, the application of a CMP process to the uppermost aluminum layer is usually not needed. As for the copper-based structures (or tungsten-based structure as well), the manufacturing process requires the use of metal removal. This is true also for processes where aluminum is deposited by the single or dual Damascene process.

With conventional technology of planarization, interlayer dielectric—ILD deposition and polishing occurs after every metal deposition and etching step. The same is not true for damascene processing, wherein the post-polish surface is expected to be free of topography. However, topography is induced because of the erosion of densely packed small feature arrays and dishing of the metal surface in large features.

Copper CMP is more complex because of the following: On the one hand, the barrier layers (such as tantalum or tantalum nitride) should be removed completely, i.e. the wafer should not be “under-polished” and/or containing residuals on its surface. On the other hand, copper should be removed without an excessive over-polishing of any feature (erosion or dishing). This is difficult to implement, because current copper deposition processes are not as uniform as the oxide deposition process. An additional problem is the occurrence of an accumulated layer-by-layer topography or non-planarity across the wafer's surface caused by erosion and dishing effects.

“Erosion” is the phenomenon that develops while the copper polishing process proceeds in time. FIG. 1A illustrates a stack-like copper-based structure 10 after the application of a CMP process thereto. The structure 10 includes an ILD bottom layer 12, the so-called “etch stop” layer 14 (e.g., SiN), ILD layer portions 16a and 16b, and a dense structure 20 including spaced-apart regions of a copper layer, generally at 18, spaced from each other by ILD layer portions 22 isolated from the surrounding oxide by a thin barrier layer (not shown). Hence, the stack layers of the dense structure 20 are composed of the ILD layer portions 22 and copper layer portions 18, and are surrounded by the ILD layer portions 16a and 16b.

Such a composite structure 10, having non-uniform mechanical and chemical properties, imposes a different polishing rate or removal distribution over the regions 16a, 16b and 20. Due to different chemical and mechanical properties of the ILD layer portions 16a and 16b, as compared to those of the small features in the dense region 20, in some cases, the polishing process proceeds quicker above the region 20, than above the portions 16a and 16b.

The CMP results in a bent-like local profile 24 (e.g. concave) of the upper surface of the structure 20. The existence of the profile 24 is called “erosion”, presenting the direct loss of ILD and metal (e.g., copper) within a region 22a.

Due to the above-mentioned factors, an additional effect, the so-called “metal line recess” designated 26 takes place presenting another type of defects on the wafer induced by the CMP process applied thereto. Yet another undesirable type of defects induced on the wafer's surface by the CMP process is the effect of barrier layer residues, designated 28, and an effect of the metal polishing called “dishing”, and relates to a non-uniform thickness removal across a relatively large non-patterned metallic area.

FIG. 1B illustrates a composite structure 110, such as a connection pad, that has undergone a CMP processing. As shown, when the metal (e.g., copper) polishing proceeds in time, it creates a profile of varying curvature depending on the process parameters, e.g., concave or convex profile 124A or 124B, respectively. This is associated with the fact that during the CMP, different values of a polishing rate or removal distribution occur over regions 116 and 120. Due to the relatively large and harder ILD layer surrounded portions 116, as compared to the metal within the pad region 120, in some cases, the polishing process proceeds quicker above the pad region 120, than the portion 116. The thickness of metal within the region 120 is a critical parameter for further integrated circuit performance, and it is strictly desirable to control this parameter to maintain it within a predetermined range. Due to the opacity of the metal (e.g., copper) layer, the conventional optical means does not provide for measuring the metal layer thickness within the areas susceptible to dishing effect.

One possible solution for minimizing the above-mentioned negative effects consists of a tight control of the CMP process, e.g. using a spectroscopy-based optical system (such as the NovaScan 210 commercially available from Nova Measuring Instruments Ltd., Israel). However, as the measured layer level increases, the complexity of the layer stack (consisting of multiple levels of OX/Etch Stop/OX/Cap layers) impairs measurement accuracy. This is due to the fact that optical measurements are performed in predetermined sites within the wafer's dies and consist of measuring the optical response of a top layer stack in these sites, while the measured parameters are affected by underlying layers. It is a very sophisticated problem to separate this influence from the top layer stack signal, which is to be measured.

### SUMMARY OF THE INVENTION

There is accordingly a need in the art to facilitate the control of a CMP process applied to patterned structures, such as semiconductor wafers having metal (e.g., copper) containing regions, by providing a novel test structure.

It is a major feature of the present invention to provide a patterned structure (which has a pattern area with spaced-apart metal-containing regions representative of real features of the patterned structure), with a test structure, which is to undergo the CMP processing together with the patterned structure, and is constructed so as to enable optical measurements of such parameters of the patterned structure that characterize the dishing effects during the CMP. By performing spectral optical measurements, the thickness of a metal layer of the patterned structure of a relatively large size can be measured.

Additionally, the invented test structure can be constructed such that, when the test structure is optically measured, it provides a substantial decrease of the lower levels' contribution to a light response of the test structure, and, when being processed by the CMP, it minimizes topology effects within the test structure.

Depending on a specific manufacturing step after which the CMP is applied to the patterned structure progressing on a production line, the test structure is formed with one or more pattern layer structures. Thus, the test structure may comprise a one-layer structure. In this case, the test structure comprises at least one pattern zone in the form of a metal area with spaced-apart regions of a material relatively transparent with respect to incident light, as compared to that of the metal spaces between these regions. In the example of a semiconductor wafer manufactured in the conventional manner, these spaced-apart regions are IDL regions. The test structure may be a stack of several layers, in which case it comprises at least two vertically aligned structures, each formed by at least one pattern zone, such that the two locally adjacent vertically aligned pattern zones are different, the lower pattern zone presents a relative opaque area, as compared to the upper pattern zone. More specifically, in the case of semiconductor wafers, the upper pattern zone is a metal area with spaced-apart IDL regions, and the lower pattern zone is the IDL area with spaced-apart metal regions. It should be noted that practically, each of the layer structures includes at least two spaced-apart different pattern zones with relatively opaque and transparent properties, as described above, aligned along a horizontal axis, such that the two pattern zones of the two layers aligned along the vertical axis are different.

Thus, according to one aspect of the present invention, there is provided a test structure, which is to be formed on a patterned structure, progressing on a production line and having a pattern area formed by spaced-apart metal-containing regions representative of real features of the patterned structure, so as to enable concurrent application of a Chemical Mechanical Planarization process to a top surface of the test structure and to a top surface of said pattern area, wherein the test structure comprises at least one pattern zone in the form of a metal area with at least one region included in the metal area and made of a material relatively transparent with respect to incident light, as compared to that of the metal.

The pattern zone may comprises the metal area with more than one region of the relatively transparent material, these regions being arranged in a spaced-apart relationship spaced by the metal.

The test structure may comprise at least one additional pattern zone in the form of an area of the relatively transparent material with one or more metal regions. These two patterns may be aligned along a horizontal axis or along a vertical axis.

According to another aspect of the present invention, there is provided a test structure, which is to be formed on a patterned structure, progressing on a production line and having a pattern area formed by spaced-apart metal-containing regions representative of real features of the patterned structure, so as to enable concurrent application of a Chemical Mechanical Planarization process to a top surface of the test structure and to a top surface of said pattern area, wherein the test structure comprises spaced-apart upper and lower pattern layer structures, each of the upper and lower structures comprising at least one pattern zone, and vertically aligned pattern zones of the upper and lower structures are different, the upper pattern zone being in the form of a metal area with at least one region included therein and made of a material relatively transparent with respect to incident light, as compared to that of the metal, and the lower pattern zone being in the form of the relative transparent area with at least one metal region included therein, the metal region being located substantially underneath the region of the relatively transparent material.

According to yet another aspect of the present invention, there is provided a patterned structure that has a pattern area formed by spaced-apart metal-containing regions representative of real features of the patterned structure, and is formed with a test site containing a test structure, which comprises at least one pattern zone in the form of a metal area with at least one region included therein and made of a material relatively transparent with respect to incident light, as compared to that of the metal.

According to yet another aspect of the present invention, there is provided a patterned structure that has a pattern area formed by spaced-apart metal-containing regions representative of real features of the patterned structure, and is formed with a test site containing a test structure, which comprises spaced-apart upper and lower pattern layer structures, each of the upper and lower structures comprising at least one pattern zone, and vertically aligned pattern zones of the upper and lower structures are different, the upper pattern zone being in the form of a metal area with at least one region included therein and made of a material relatively transparent with respect to incident light, as compared to that of the metal, and the lower pattern zone being in the form of the relative transparent area with at least one region metal region included therein, the metal region being located substantially underneath the region of the relatively transparent material

According to yet another aspect of the present invention, there is provided a method of controlling a process of Chemical Mechanical Planarization (CMP) applied to a group of similar patterned structures progressing on a production line, each pattern structure having a pattern area formed by spaced-apart metal-containing regions representative of real features of the patterned structure, the method comprising the steps of:

(a) forming at least one of the patterned structures progressing on a production line with a test site containing a test structure, which comprises at least one pattern zone in the form of a metal area with at least one region included in the metal area and made of a material relatively transparent with respect to incident light, as compared to that of the metal;

(b) applying the CMP process to the patterned structure, thereby processing both the test structure and the pattern area;

(c) applying optical measurements to the processed test structure to detect an optical response of the test structure;

(d) analyzing the detected optical response to determine whether there exists at least one of erosion and dishing effects caused by the CMP processing, the analysis of the optical response enabling to adjust a working parameter of the CMP process prior to applying the CMP process to another patterned structure.

### BRIEF DESCRIPTION OF THE DRAWINGS

In order to understand the invention and to see how it may be carried out in practice, a preferred embodiment will now be described, by way of non-limiting example only, with reference to the accompanying drawings, in which:

FIG. 1A is a schematic illustration of the section of a wafer's fragment after the application of the CMP process to the wafer, showing more specifically the erosion, metal recess and residual effect;

FIG. 1B is a schematic illustration of the section of a wafer's fragment after the application of the CMP process to the wafer, showing more specifically the dishing effect;

FIG. 2 is a schematic top view of a test structure according to one embodiment of the present invention; and

FIGS. 3A and 3B schematically illustrate a test structure according to another embodiment of the invention utilizing the test structure of FIG. 2.

### DETAILED DESCRIPTION OF THE INVENTION

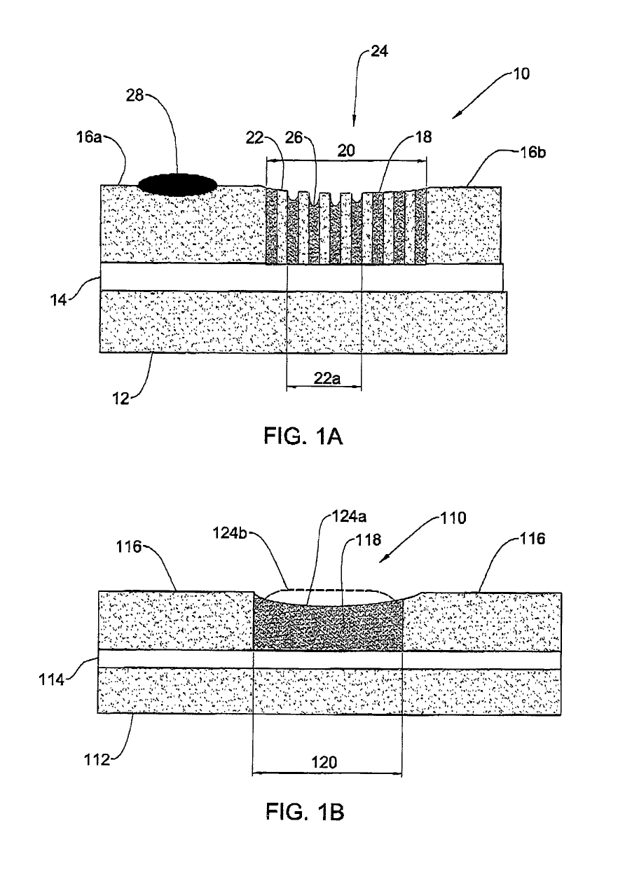

More specifically, the present invention is used for controlling a CMP process applied to semiconductor wafers (constituting patterned structures with real pattern features) progressing on a production line in the semiconductor devices' manufacture, and is therefore described below with respect to this application. FIG. 1A and 1B illustrate a wafer after the application of the CMP process thereto, and show the erosion, metal recess and residual effects (FIG. 1A) and the dishing effect (FIG. 1B)

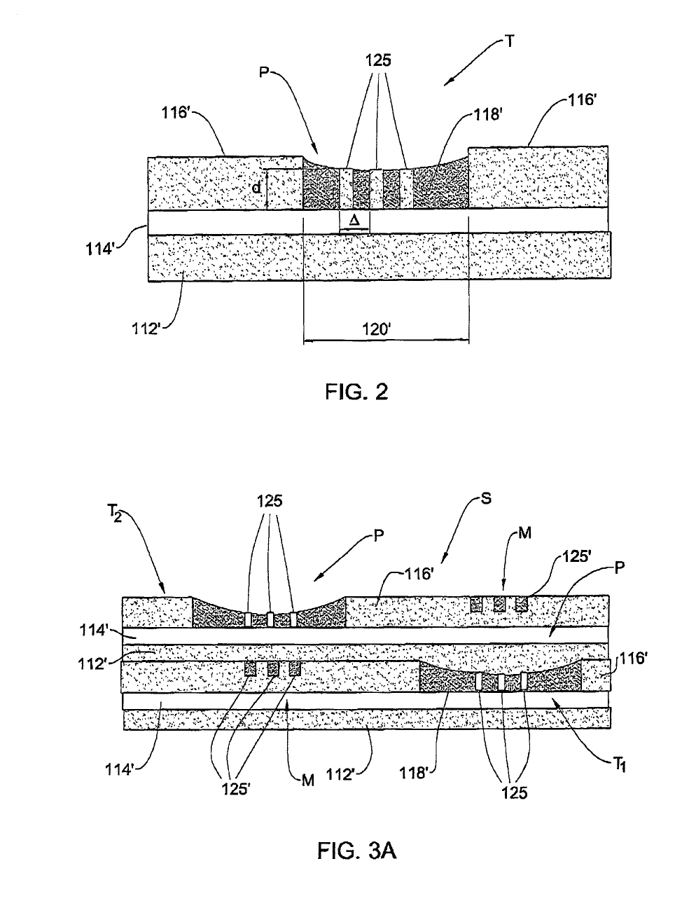

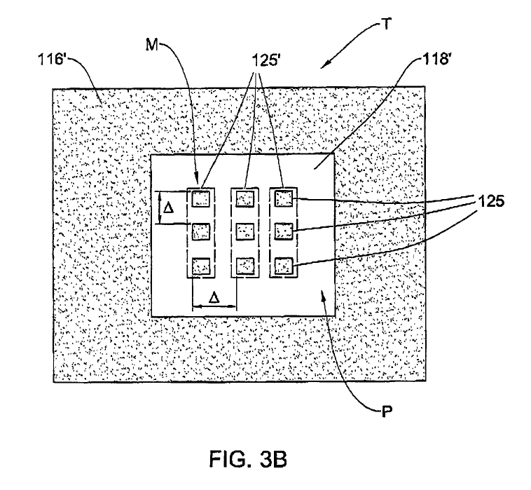

Referring to FIGS. 2 and 3, there is illustrated a test structure T according to one embodiment of the invention. Preferably, the test structure is to be located in the scribe lines (or margins) of the wafer, thereby enabling optical measurements of desired parameters of the test structure for tight monitoring the CMP process applied to the wafer. The test structure T includes an ILD bottom layer 112′, an etch stop layer 114′ (e.g., SiN), ILD layer portions 116′ , and a relatively large metal pad-like area 120′ surrounded by the harder ILD layer portion 116′ and comprising ILD inclusions 125 in the metal layer 118′. Preferably, the inclusions 125 have a rod-like form having a height d, and are located in the central region of the pad-like area 120′.

A pattern metal density or duty cycle D and a pitch Δ should be chosen so as to provide similar effects that can be induced by the CMP process in the test structure and in the pattern area of the wafer conditions. The pitch, Δ, is a distance between corresponding points on two locally adjacent similar pattern elements, and the duty cycle, D, is defined as the ratio of the width W_{inc} of the ILD inclusion 125 to the pitch Δ, i.e., D=W_{inc/Δ}. It should be noted that the pitch Δ of the pattern is chosen due to limitations of the measuring and interpretation technique. Other process parameters, such as the slurry chemical selectivity and the most prominent effect to be monitored, should also be considered. Thus, by measuring the thickness of the IDL layer within the region 116′ in the vicinity of the area 120′, and by measuring the thickness d of the IDL inclusion 125 within the area 120′, the dishing effect can be detected.

Thus, the test structure T comprises a pattern zone P in the form of the metal area 118′ with the ILD inclusions 125 (constituting a relatively transparent material as compared to the metal). Although in the present example, an array of such inclusions is presented, it should be noted that the provision of only one ILD inclusion may be sufficient, depending on the size of a light beam to be used for optical measurements.

Reference is now made to FIGS. 3A and 3B schematically illustrating a test structure S on a wafer comprising two structures T₁ and T₂ aligned along a vertical axis, thereby forming two adjacent “levels”. To simplify understanding, the same reference numbers are used for identifying components that are common in the examples of FIGS. 2 and 3A-3B. It should be understood that number of “levels” in the test structure S is selected in correspondence with the number of “levels ” in the wafer. According to the conventional technology of manufacture of semiconductor devices, a semiconductor wafer is processed by sequential applying layers of different materials. The resulting wafer stack could comprise, for example, about 20-30 different layers. In the present example, only layers laid between the two structures bearing layers are shown, being separated by the “etch stop” 114′ and oxide layers 112′.

Each of the structures T₁ and T₂ comprises two pattern zones P and M, wherein the pattern in the zone P is in the form of spaced-apart inclusions 125 in the metal 118′, and the pattern in the zone M is in the form of spaced-apart metal lines 125′ in the ILD layer 114′. The structures are arranged with respect to each other such that the zone P in the upper structure T₂ (layer) is aligned along the vertical axis with the zone M in the lower structure T₁ (layer). For example, this can be implemented by 180°-rotation of one structure with respect to the other. It should be understood that the duty cycle of the pattern M is determined as the ratio between the width of the metal line 125′ and the respective pitch. Thus, the pattern zone P of the upper structure T₂ (“level”) is located above the pattern zone M of the lower “level’.

The main two aspects define the design rules of such a test structure S. On the one hand, it is necessary to substantially reduce the lower levels' contribution to the light response (reflection) signal of the rods (ILD inclusions 125). This is implemented by introducing a relatively opaque structure, e.g., extremely rich metal pattern, underneath the zone with these inclusions. On the other hand, the presence of a large metal area such as pad-like structure underneath the top layer to be processed by the CMP will evidently cause dishing in the top layer and will severely affect the measurement area planarity. For these purposes, the structures T₁ and T₂ are arranged such that the metal regions containing zones M (i.e., relatively opaque as compared to the ILD inclusions containing zones P) are located under the zones P. The metal regions containing zones M could be made in the form of strips located under the ILD inclusions 125.

The parameters of the zone P are chosen in accordance with the parameters of the upper structure T₂ so as to provide an acceptable optical isolation of the ILD inclusions 125 from the underneath layers. In order to avoid the problem of topography, the pattern zone M is such that its metal containing regions 125′ have possibly minimal dimensions, providing sufficient optical isolation of the lower levels' contribution. The optical isolation of the lower levels' contribution by introducing a relatively opaque area underneath the relatively transparent area extremely simplifies the measuring procedure, since the complicated stack comprising all the lower levels could be substituted by relatively simple stack, comprising limited number of layers. In some cases of complicated stack structure, it is practically impossible to obtain desired dishing parameters such as thickness of a metal layer by indirect optical measurements.

A consideration in choosing the parameters of pattern formed by the ILD inclusions 125 such as size, pitch A and metal density D, could be the limitations of the measuring and interpretation technique.

The measuring technique does not form part of the present invention and need not be specifically described except to note the following. One example of a measuring technique suitable to be applied to the test structure according to the present invention is disclosed in the U.S. Pat. No. 6,100,985, assigned to the assignee of the present application, which is therefore incorporated herein by reference. This measuring technique utilizes a two-dimensional model capable of determining theoretical data representative of photometric intensities of light components of different wavelengths reflected from a test structure, and calculating desired parameters (e.g., thickness d) of the structure layers. An appropriate test structure including ILD inclusions (125 (in FIGS. 3A and 3B) to be measured by this technique, is characterized by metal density D over 70%, i.e., the size of the ILD inclusions 125 is substantially smaller than that of the adjacent surrounded metal areas. The size of the inclusions 125 could be, for example, about 1 μm, and the distance therebetween (metal areas) about 3 μm. The specific parameters of a test structure to be used in this measuring technique, i.e., widths and lengths, are preferably determined by the measurement spot-size. Alternatively or additionally, according to the dimensions of the pattern structure, different known diffraction techniques, such as Rigorous Coupled Wave Theory (RCWT) for example, could be used for measuring. Another example of the technique that could be used for measuring desired parameters of a test structure designed in accordance with the present invention is disclosed in the co-pending U.S. application Ser. No. 09/326,665, assigned to the assignee of the present application, which application is therefore incorporated herein by reference.

The presence of the ILD inclusions 125 (zone P) in the test structure enables optical measurements of the parameters characterizing the dishing effect during the CMP process. By performing spectral optical measurements, the thickness d of a metal layer of the test structure (corresponding to that of then real pattern area in the wafer) with a relatively large size could be measured. The test structure according to the invention is thus intended to provide the metal thickness (or level) d, characterizing the dishing effect. The presence of the pattern zone M in the upper layer or “level” could provide additional information on the erosion, local dishing and metal lines thickness measurements.

An additional effect provided by the above-described inverted orientation of the pattern zones in the adjacent levels of the test structure is the planarity of the upper surface of the entire test structure. Each consequent or upper level structure has an inverted orientation with respect to that of the lower level and vice versa, thus achieving, on average, a planar surface.

In addition, the thickness of the metal layer in a real metal pad or pads in the wafer could be measured using various known techniques, such as X-ray, SEM, etc., and the correlation between the thickness of the metal layer measured in the test structure and that measured in the real wafer could be determined. Hence, it is possible to eliminate or at least substantially decrease the influence of the ILD inclusions on the metal polishing process in the test structure, and using such a calibration, the dishing process on the metal pads in the real wafer is estimated more precisely and reliably.

Thus, a semiconductor wafer formed with a test structure according to the invention within the scribe lines of the wafer, is supplied to a CMP station associated with a spectrophotometer-based optical monitoring system (i.e., the so-called “Integrated Monitoring”). When the CMP processing is applied to the wafer, the test site undergoes the same processing as the real-features-containing area of the wafer. Thereafter, the processed wafer is transferred to the monitoring system, which may and may not be mounted within the CMP station, and measurements are applied to the test site on the wafer. The analysis of the measurement results allows for adjusting the working parameters of the CMP tool (such as the speed and/or time of polishing) prior to applying the tool to a further wafer.

Obviously, many modifications and variations of the present invention are possible in the light of the above teachings. Those skilled in the art will readily appreciate that many modifications and changes may be applied to the invention as hereinbefore exemplified without departing from its scope, as defined in and by the appended claims.

1. A test structure, which is to be formed on a patterned structure, progressing on a production line and having a pattern area formed by spaced-apart metal-containing regions representative of real features of the patterned structure, so as to enable concurrent application of a Chemical Mechanical Planarization process to a top surface of the test structure and to a top surface of said pattern area, wherein the test structure comprises at least one pattern zone in the form of a metal area with at least one region included in the metal area and made of a material relatively transparent with respect to incident light, as compared to that of the metal.

2. The test structure according to claim 1, wherein the at least one pattern zone comprises at least one additional region of the relatively transparent material, the at least two regions of the relatively transparent material being aligned in a spaced-apart parallel relationship in the metal area.

3. The test structure according to claim 1, and also comprising an additional pattern zone in the form of an area of the relatively transparent material with at least one metal region included therein, the test structure thereby comprising at least two spaced-apart different pattern zones.

4. The test structure according to claim 3, wherein the additional pattern zone comprises at least one additional metal region, the at least two metal regions being aligned in a spaced-apart parallel relationship in the area of the relatively transparent material.

5. The test structure according to claim 3, wherein the two different pattern zones are aligned in a spaced-apart relationship in a common plane.

6. The test structure according to claim 3, wherein the two different pattern zones are located in two spaced-apart layers presenting upper and lower pattern structures, respectively, of the test structure, such that the upper pattern zone is in the form of the metal area with the at least one region of the relatively transparent material, and the lower pattern zone is in the form of the area of the relatively transparent material with the at least one metal region, the metal region being located substantially underneath the region of the relatively transparent material.

7. The test structure according to claim 5, and also comprising two additional patterns zones, the four pattern zones being arranged such that the two different pattern zones are located in a spaced-apart relationship in an upper layer, and the other two different pattern zones are located in a spaced-apart relationship in a lower layer, and such the pattern zone in the form of the area of the relatively transparent material with the at least one metal region is vertically aligned with the pattern zone in the form of the metal area with the at least one region of the relatively transparent material, the metal region being located substantially underneath the region of the relatively transparent material.

8. A test structure, which is to be formed on a patterned structure, progressing on a production line and having a pattern area formed by spaced-apart metal-containing regions representative of real features of the patterned structure, so as to enable concurrent application of a Chemical Mechanical Planarization process to a top surface of the test structure and to a top surface of said pattern area, wherein the test structure comprises spaced-apart upper and lower pattern layer structures, each of the upper and lower structures comprising at least one pattern zone, and vertically aligned pattern zones of the upper and lower structures are different, the upper pattern zone being in the form of a metal area with at least one region included therein and made of a material relatively transparent with respect to incident light, as compared to that of the metal, and the lower pattern zone being in the form of the relative transparent area with at least one metal region included therein, the metal region being located substantially underneath the region of the relatively transparent material.

9. A patterned structure that has a pattern area formed by spaced-apart metal-containing regions representative of real features of the patterned structure, and is formed with a test site containing a test structure, which comprises at least one pattern zone in the form of a metal area with at least one region included therein and made of a material relatively transparent with respect to incident light, as compared to that of the metal.

10. A patterned structure that has a pattern area formed by spaced-apart metal-containing regions representative of real features of the patterned structure, and is formed with a test site containing a test structure, which comprises spaced-apart upper and lower pattern layer structures, each of the upper and lower structures comprising at least one pattern zone, and vertically aligned pattern zones of the upper and lower structures are different, the upper pattern zone being in the form of a metal area with at least one region included therein and made of a material relatively transparent with respect to incident light, as compared to that of the metal, and the lower pattern zone being in the form of the relative transparent area with at least one region metal region included therein, the metal region being located substantially underneath the region of the relatively transparent material.

11. The patterned structure according to claim 9, being a semiconductor wafer progressing on a production line in a process of manufacturing semiconductor devices, the pattern zone being the metal area with the at least on dielectric region.

12. The patterned structure according to claim 10, being a semiconductor wafer progressing on a production line in a process of manufacturing semiconductor devices, the pattern zone being the metal area with the at least one dielectric region.

13. A method of controlling a process of Chemical Mechanical Planarization (CMP) applied to a group of similar patterned structures progressing on a production line, each pattern structure having a pattern area formed by spaced-apart metal-containing regions representative of real features of the patterned structure, the method comprising the steps of:
(a) forming at least one of the patterned structures progressing on a production line with a test site containing a test structure, which comprises at least one pattern zone in the form of a metal area with at least one region included in the metal area and made of a material relatively transparent with respect to incident light, as compared to that of the metal;
(b) applying the CMP process to the patterned structure, thereby processing both the test structure and the pattern area;
(c) applying optical measurements to the processed test structure to detect an optical response of the test structure;
(d) analyzing the detected optical response to determine whether there exists at least a dishing effect caused by the CMP processing, the analysis of the optical response enabling to adjust a working parameter of the CMP process prior to applying the CMP process to another patterned structure.

14. The method according to claim 13, wherein measurement results include a thickness of the metal area characterizing the dishing effect.

15. The method according to claim 14, wherein step (iii) comprises a measurement applied to a location on the test site in the vicinity of the pattern zone to determine the thickness of a dielectric layer presenting said relatively transparent material surrounding the pattern zone, and a measurement of the thickness of the dielectric material in the pattern zone.

16. The method according to claim 13, wherein the test structure comprises an additional pattern zone in the form of an area of the relatively transparent material with at least one metal region included therein, the two different pattern zones being located in a spaced-apart relationship in a common plane, measurement results including information on erosion, local dishing and metal regions thickness.

17. The method according to claim 13, wherein the test structure comprises an additional pattern zone in the form of an area of the relatively transparent material with at least one metal region included therein, the two different pattern zones being located in two spaced-apart layers presenting upper and lower pattern layer structures, respectively, of the test structure, the metal region being located substantially underneath the region of the relatively transparent material, the detected optical response being thereby substantially unaffected by optical response of the lower pattern structure.
